(19) United States
(12) Patent Application Publication
(10) Pub. No.: US 2023/0327394 A1
(43) Pub. Date: Oct. 12, 2023

(54) OPTOELECTRONIC SEMICONDUCTOR COMPONENT, PRODUCTION METHOD, AND BASE

(71) Applicant: OSRAM OPTO SEMICONDUCTORS GMBH, Regensburg (DE)

(72) Inventors: Jörg Erich SORG, Regensburg (DE); Roland HUETTINGER, Kaufering (DE); Matthias HOFMANN, Regensburg (DE); Steffen STRAUSS, Nittendorf (DE); Herbert BRUNNER, Sinzing (DE); Ralph WAGNER, Neutraubling (DE)

(73) Assignee: ams-OSRAM International GmbH, Regensburg (DE)

(21) Appl. No.: 18/005,876

(22) PCT Filed: Jul. 15, 2021
(86) PCT No.: PCT/EP2021/069736

§ 371 Date: Jan. 18, 2023

(30) Foreign Application Priority Data
Jul. 21, 2020 (DE) 10 2020 119 192.8
Feb. 18, 2021 (DE) 10 2021 103 863.4

(51) Int. Cl. H01S 5/02257; H01S 5/02224

(52) U.S. Cl. CPC H01S 5/02257; H01S 5/02224; H01S 5/4093

(57) ABSTRACT

In one embodiment, the optoelectronic semiconductor component includes at least one optoelectronic semiconductor chip for generating radiation and a housing, in which the at least one optoelectronic semiconductor chip is hermetically encapsulated. The housing includes a housing cover which is secured to a housing main part by a connection means. The housing additionally includes a gas exchange channel which is hermetically sealed by a seal.

### CROSS-REFERENCE TO RELATED APPLICATIONS

This patent application is a national stage entry from International Application No. PCT/EP2021/069736, filed on Jul. 15, 2021, published as International Publication No. WO 2022/017905 A1 on Jan. 27, 2022, and claims priority to German Patent Application Nos. 10 2020 119 192.8, filed Jul. 21, 2020, and 10 2021 103 863.4, filed Feb. 18, 2021, the disclosures of all of which are incorporated by reference herein in their entireties.

### FIELD OF THE INVENTION

An optoelectronic semiconductor component is specified. Additionally specified is a method for producing such an optoelectronic semiconductor component. Specified lastly is a baseplate for such an optoelectronic semiconductor component.

### BACKGROUND OF THE INVENTION

One problem to be solved is that of specifying an optoelectronic semiconductor component which has a long lifetime.

Solutions to this problem include an optoelectronic semiconductor component, a production method, and a baseplate, having the features of the independent claims. Preferred developments are subject matter of the dependent claims.

### SUMMARY OF THE INVENTION

According to at least one embodiment, the semiconductor component comprises one or more optoelectronic semiconductor chips. The at least one optoelectronic semiconductor chip is configured for generating a radiation which is more particularly visible light.

Where two or more optoelectronic semiconductor chips are present, they serve preferably for generating radiation of different wavelengths, i.e., in particular, for generating blue, green, and red light, thus allowing different-colored light to be emitted via an actuation of the optoelectronic semiconductor chips. The at least one optoelectronic semiconductor chip is preferably a laser diode, although light-emitting diodes, LEDs for short, or combinations of laser diodes and light-emitting diodes, may also be used.

According to at least one embodiment, the optoelectronic semiconductor component comprises a housing. The at least one optoelectronic semiconductor chip is encapsulated in the housing.

According to at least one embodiment, the housing is hermetically impervious and the at least one optoelectronic semiconductor chip is therefore accommodated in the housing with hermetic encapsulation. This means that between an interior and an exterior of the housing, there is no significant exchange of substances such as oxygen, nitrogen or water vapor. Hermetically impervious means, for example, that the leakage rate of the housing is at most 5×10⁻⁹ Pa m/s or at most 5×10⁻⁸ Pa m/s or at most 5×10⁻⁷ Pa m/s, especially at room temperature. It is possible accordingly to attain a long lifetime for the semiconductor component.

According to at least one embodiment, the housing comprises a housing cover, more particularly exactly one housing cover. The housing cover, which is composed for example of a glass, is secured on a main body of the housing by a connecting means. The main housing body is based, for example, on one or on two or more ceramics, or else on at least one semiconductor material or at least one metal. The connecting means may comprise, for example, a solder, such as a metallic solder or glass solder, or else, alternatively, an adhesive, which may be based on an organic material.

According to at least one embodiment, the housing comprises a gas exchange channel. The gas exchange channel is configured to allow, in the opened state, an exchange of gas between a cavity within the housing and an external environment. The gas exchange channel is preferably needed only during the production of the semiconductor component and may therefore be without function in the completed semiconductor component. The gas exchange channel is, in particular, small in comparison to overall dimensions of the housing.

According to at least one embodiment, the gas exchange channel is sealed hermetically with one or with two or more seals. This means that the hermetic imperviousness of the housing is actually achieved, as part of the production operation, in particular by the sealing of the gas exchange channel with the seal.

In at least one embodiment, the optoelectronic semiconductor component comprises at least one optoelectronic semiconductor chip for generating a radiation, and a housing in which the at least one optoelectronic semiconductor chip is hermetically encapsulated. The housing comprises a housing cover, which is secured on a main housing body using a connecting means. The housing also comprises a gas exchange channel which is hermetically sealed with a seal.

Semiconductor components such as RBG laser modules are stored and also operated preferably in an inert gas atmosphere or in a forming gas atmosphere. This means that around the semiconductor component there is then an atmosphere which is preferably oxygen-free and water-free, or substantially oxygen-free and water-free. Within the housing, however, there is preferably an oxygen-containing atmosphere, specifically on a laser facet in a light exit region for laser radiation out of the optoelectronic semiconductor chip.

This means that in the event of the encapsulation of the optoelectronic semiconductor chip being not of high quality, the oxygen fraction within the housing decreases over time, possibly leading to a curtailed lifetime. At the start of operation, therefore, a comparatively high oxygen content should be provided in the cavity, in order to keep sufficient oxygen in the housing over the lifetime of the semiconductor component.

On the other hand, during the sealing of the housing, there is preferably an oxygen-free or low-oxygen atmosphere present, in order to prevent oxidation of the connecting means at elevated temperatures. Such oxidation may result in reduced soldering quality and hence in a lower imperviousness of the housing and/or in a low soldering yield.

The requirements with regard to the atmosphere during operation and during production of the semiconductor component are therefore different. By means of the gas exchange channel in the semiconductor component described here, it is possible to provide different atmospheres, independently of one another, during the assembly of the housing and in final operation, so making it possible to achieve enhanced imperviousness of the housing and an extended lifetime of the optoelectronic semiconductor chip.

According to at least one embodiment, only exactly one gas exchange channel is installed in the housing. This ensures that the imperviousness of the housing is barely affected by the sealing of the gas exchange channel.

According to at least one embodiment, the gas exchange channel is electrically and optically, and preferably also mechanically, function-free. This means that the gas exchange channel and, in connection therewith, the seal as well do not fulfill any operationally relevant functions in the proper operation of the semiconductor component, apart from keeping the housing impervious. More particularly, none, or no significant fraction, of the radiation generated in operation impinges on the gas exchange channel or the seal, and no, or no significant electrical current flows via the gas exchange channel or the seal, and preferably there is also no defined voltage different from a ground potential.

According to at least one embodiment, the main housing body comprises a baseplate, which is preferably opaque for the radiation generated in operation. The baseplate serves as a carrier for the at least one optoelectronic semiconductor chip. This means that the baseplate constitutes a mounting side for the at least one optoelectronic semiconductor chip.

According to at least one embodiment, the baseplate bears metallic electrical connection regions on at least one main side, preferably both sides. The connection regions are embodied, for example, as electrical conductor tracks and/or as electrical contact faces. The connection regions are configured more particularly for solder contacting and/or for the installation of bond wires.

Corresponding connection regions on different sides of the baseplate are preferably connected electrically to one another by electrical interlayer connections, also referred to as vias. It is possible for the interlayer connections, seen in plan view on the mounting side, to be located exclusively within the baseplate, in other words surrounded all round by an electrically insulating material of the baseplate.

According to at least one embodiment, the housing cover is configured as a radiation exit window for the radiation generated in operation. For this purpose the housing cover may bare one or two or more optically active coatings, such as, for example, antireflection coatings, and/or optical filter layers. Moreover, the housing cover may be shaped at least locally as an optical unit and may therefore act, for instance, as a lens.

According to at least one embodiment, the gas exchange channel is located in the baseplate, more particularly exclusively in the baseplate. This means that the gas exchange channel may be on a bottom housing side that is no longer visible later in the mounted state of the semiconductor component.

According to at least one embodiment, the gas exchange channel comprises one or more metallizations. The at least one metallization is preferably thinner, at least on the bottom housing side, than the electrical connection regions. This means that the electrical connection regions, especially on the bottom side of the housing, protrude beyond the gas exchange channel and the seal in a direction away from the main housing body. Alternatively the electrical connection regions finish flush with the seal or else with the gas exchange channel.

According to at least one embodiment, the gas exchange channel, seen in plan view onto the mounting side, is located adjacent to the at least one optoelectronic semiconductor chip. This prevents or minimizes steric influencing of the semiconductor chip by the gas exchange channel. The gas exchange channel is preferably also adjacent to the electrical connection regions and/or is insulated from them electrically.

According to at least one embodiment, the gas exchange channel is located in the housing cover, more particularly only in the housing cover. In this case, the gas exchange channel is arranged preferably at a distance from a beam path of the radiation generated in operation, in order to prevent or minimize any influencing of the radiation.

According to at least one embodiment, the main housing body comprises one or more carrier rings on a side facing the housing cover. The at least one carrier ring therefore acts as a spacer between the main housing body and the housing cover. The height of the cavity in the housing may be efficiently adjusted through the geometry of the carrier ring and/or through the number of carrier rings.

According to at least one embodiment, the gas exchange channel is located in the carrier ring, especially exclusively in the carrier ring. By means of such an arrangement of the gas exchange channel, the lateral extent of the housing, more particularly the size of the baseplate, may be reducible.

According to at least one embodiment, the seal comprises or consists of a low-melting glass. The low-melting glass preferably has a melting point of at most 500° C. or of at most 400° C. or of at most 350° C. The glass is, for example, a glass solder.

According to at least one embodiment, the seal comprises a metal or a metal alloy or consists of at least one metal or of at least one metal alloy. More particularly the seal comprises gold or is composed of gold. In that case the seal is formed, for example, of a stud bump for a bond wire or of a gold flake applied, for example, by means of friction welding, as for example by means of thermosonic bonding. This is especially the case if the gas exchange channel has the metallization.

It is possible, furthermore, for the seal to be a gold alloy or to comprise a gold alloy—for example, AuGa₂ or an alloy with Au, Ga, and In. It is possible, moreover, for the seal to comprise or consist of Cu, Ni, Zn, Sn in combination with Hg.

According to at least one embodiment, the seal comprises a metallic solder or consists of a metallic solder. The solder is, for example, a soft solder such as AuSn.

According to at least one embodiment, the seal comprises or consists of a carrier plate and a sealing layer. The sealing layer here is located between the carrier plate and the gas exchange channel. The sealing layer is composed more particularly of a friction-weldable metal such as gold or else of a metallic solder or glass solder. The sealing layer may be applied flatly on the carrier plate or may be located as a frame only at an edge of the carrier plate, or alternatively may also be present only in a central region of the carrier plate.

According to at least one embodiment, the mean diameter of the gas exchange channel is at least 2 μm or at least 5 μm or at least 10 μm or at least 20 μm. Alternatively or additionally, the mean diameter is at most 0.4 mm or at most 0.2 mm or at most 0.1 mm or at most 0.05 mm. For example, the mean diameter is between 2 μm and 200 μm inclusive or between 5 μm and 80 μm inclusive or between 20 μm and 80 μm inclusive.

According to at least one embodiment, the thickness of the housing directly at the gas exchange channel exceeds the mean diameter of the gas exchange channel by a factor of at least two or by a factor of at least four. This means, relative to the thickness of the housing, more particularly of the baseplate, of the carrier ring or of the housing cover, the gas exchange channel is thin.

According to at least one embodiment, the gas exchange channel is filled partly with the seal, to an extent, for example, of at least 5% and/or at most 50% or at most 20%. This means that the gas exchange channel may be predominantly free of the seal.

Alternatively the seal only covers the gas exchange channel and does not fill the gas exchange channel or fills it only marginally, to an extent, for example, of at most 1% or at most 5% or at most 10%. In a further alternative, the seal may fill the gas exchange channel completely or almost completely, to an extent, for example, of at least 90% or 95%.

According to at least one embodiment, the optoelectronic semiconductor component is a laser module for generating red, green, and blue light, i.e., an RGB module. Accordingly the semiconductor component comprises preferably multiple laser diodes which emit with different colors and can be actuated independently of one another.

According to at least one embodiment, the semiconductor component is surface-mountable. This means that the housing can be installed on an external connection carrier, such as a printed circuit board, by means of SMT—surface mount technology.

According to at least one embodiment, the gas exchange channel has the shape of a cylinder, a conical frustum or a double cone. The gas exchange channel preferably has a cylindrical design or the shape of a conical frustum.

According to at least one embodiment, the housing cover is composed of a glass, of a ceramic or of sapphire. In this case the housing lid is preferably in one piece. Alternatively the housing lid may be composed of multiple components—for example, of a ceramic plate in combination with a radiation exit window composed of glass or sapphire.

According to at least one embodiment, the main housing body is based on one or on two or more ceramics. For example, the main housing body comprises a baseplate composed of AlN and a carrier ring composed of AlN or of Al₂O₃. The main housing body based on at least one ceramic may mean that the only electrically insulating material of the main housing body is the at least one ceramic.

According to at least one embodiment, at least one optical unit for the radiation generated in operation is located in the housing. The at least one optical unit is, for example, a deflecting mirror, a movable mirror such as a MEMS mirror, and/or a focusing component such as a collecting lens.

Furthermore, a method is specified, for producing an optoelectronic semiconductor component, for example, as described in connection with one or more of the embodiments stated above. Features of the optoelectronic semiconductor component are therefore also disclosed for the method, and vice versa.

In at least one embodiment, the method serves for producing an optoelectronic semiconductor component having a housing, and comprises the following steps, more particularly in the specified order:
A) equipping a main housing body with at least one optoelectronic semiconductor chip, the main housing body having at least one gas exchange channel,
B) installing a housing cover on the main housing body, and
D) sealing the gas exchange channel with a seal, so that the housing is hermetically sealed.

In at least one embodiment, the method serves for producing an optoelectronic semiconductor component and comprises the following steps, preferably in the specified order:
A) equipping the main housing body with the at least one optoelectronic semiconductor chip,
B) installing the housing cover on the main housing body, there being a first atmosphere for the working of the connecting means in the housing,
C) replacing the first atmosphere in the housing with a second atmosphere through the open gas exchange channel, and
D) sealing the gas exchange channel with the seal, so that the housing is hermetically sealed.

As a result of this it is possible, through the first atmosphere, to achieve a high-quality connection point between the housing cover and the main housing body, and it is possible subsequently to introduce a second atmosphere into the housing that is optimized for the operation of the at least one optoelectronic semiconductor chip.

According to at least one embodiment, the first atmosphere is a protective gas atmosphere, an inert atmosphere and/or a forming gas atmosphere.

According to at least one embodiment, the second atmosphere is oxygen-containing. For example, the second atmosphere is formed by dried and/or purified air and in that case consists substantially of oxygen, nitrogen, and argon, and also CO₂. The oxygen fraction of the second atmosphere during the filling of the housing is therefore preferably between 10% and 30% inclusive, more particularly around 21%. A dew point temperature of the second atmosphere is preferably at most −60° C. or −80° C., and so the second atmosphere is virtually water-free.

According to at least one embodiment, the sealing of the gas exchange channel comprises the coating of an inner side of the gas exchange channel with at least one metallization. The metallization, for example, comprises or consists of gold and/or copper. The metallization may be formed of a single metal layer. Alternatively the metallization may be composed of two or more metal layers, which may also be applied alternately. It is not necessary for the metallization to be limited to the inner side, and so the metallization may optionally extend over regions of the housing that directly border the gas exchange channel.

The metallization may be produced even before the equipping of the main housing body with the at least one optoelectronic semiconductor chip. This means that a part of step D) may take place even before step A), and the completion of step D) may be brought about only after steps A), B) and/or C).

According to at least one embodiment, the metallization has a thickness which is at least 5% or at least 10% or at least 20% of the mean diameter of the gas exchange channel. Alternatively or additionally this thickness is at most 30% or at most 20% of the mean diameter.

According to at least one embodiment, the sealing of the gas exchange channel comprises the introduction of at least one alloy metal into the gas exchange channel. On introduction the alloy metal is preferably liquid. Accordingly, the at least one alloy metal makes contact with the metallization and is able to react with the metallization. The alloy metal is, for example, gallium or a mixture of gallium and indium, especially for gold-based metallizations, or the alloy metal is mercury, especially for metallizations based on copper, nickel, tin and/or zinc. It is introduced more particularly at room temperature or approximately at room temperature, as for example at at least 15° C. or at least 25° C. and/or at most 75° C. or at most 55° C. or at most 40° C. The alloy metal is preferably different from the material of the metallization.

According to at least one embodiment, the sealing of the gas exchange channel comprises hardening to form the seal, with the at least one alloy metal reacting with the metallization. The hardening is more particularly an amalgamation. As a result of the hardening or full reacting, therefore, a sealing alloy is formed which with particular preference has a higher melting point than the at least one alloy metal, which in particular was formerly liquid at approximately room temperature.

According to at least one embodiment, the hardening or amalgamation takes place at approximately room temperature, as for example at a temperature of at least 15° C. or of at least 50° C. or of at least 80° C. Alternatively or additionally, this temperature is at most 250° C. or at most 150° C. or at most 100° C.

According to at least one embodiment, the hardening or amalgamation is carried out for a time of at least 1 h or at least 2 h or at least 5 h. Alternatively or additionally the curing or amalgamation lasts at most 30 d or at most 5 d or at most 48 h.

It is possible for the hardening or amalgamation to be assisted by a particular gas atmosphere, such as a protective gas atmosphere, for instance nitrogen or argon. In addition, the curing or amalgamation may take place optionally at relatively high atmospheric pressure or hydraulic pressure of the liquid alloy metal. For example, the atmospheric and/or hydraulic pressure at least at times during the curing or amalgamation exceeds 1 bar or 2 bar or 5 bar. It is possible, before complete closing of the gas exchange channel, for the atmospheric pressure to be reduced to standard pressure and/or for the hydraulic pressure to be increased after the complete closing of the gas exchange channel.

Additionally specified is a baseplate for an optoelectronic semiconductor component, as described in connection with one or more of the embodiments stated above. Features of the optoelectronic semiconductor component are therefore also disclosed for the baseplate, and vice versa.

In at least one embodiment, the baseplate is intended for an optoelectronic semiconductor component. The baseplate is configured as a carrier for at least one optoelectronic semiconductor chip and bears metallic electrical connection regions, on both sides, for the electrical interconnection of the at least one optoelectronic semiconductor chip. Located in the baseplate is a gas exchange channel which comprises a metallization. The metallization, at least on a bottom side of the baseplate that is opposite a mounting side for the at least one optoelectronic semiconductor chip, is thinner than the electrical connection regions. Furthermore, on the bottom side, the electrical connection regions protrude beyond the gas exchange channel in a direction away from the baseplate. The gas exchange channel, seen in plan view onto the mounting side, is located adjacent to a region intended for the at least one optoelectronic semiconductor chip, and is preferably insulated from the electrical connection regions electrically. Lastly, on the bottom side, the gas exchange channel has an area fraction of at most 1% or at most 0.2%, seen in plan view onto the bottom side.

The optoelectronic semiconductor components described here may be employed, for example, in projection applications or in goggles for virtual or augmented reality. This is made possible in particular through the compact construction of the hermetically impervious housing.

### BRIEF DESCRIPTION OF THE DRAWINGS

Below, a here-described optoelectronic semiconductor component, a here-described method, and a here-described baseplate are elucidated in more detail with reference to the drawing, using exemplary embodiments. Identical reference symbols denote identical elements in the individual figures. However, no references of scale have been shown; instead, individual elements may be represented with excessive size in order to aid understanding.

In the drawing:

FIG. 1 shows a schematic plan view onto a baseplate for exemplary embodiments of here-described optoelectronic semiconductor components,

FIG. 2 shows a schematic sectional representation of the baseplate from FIG. 1,

FIGS. 3 to 7 show schematic sectional representations of steps of an exemplary embodiment to a method for producing here-described optoelectronic semiconductor components,

FIGS. 8 to 10 show schematic sectional representations of exemplary embodiments of here-described optoelectronic semiconductor components,

FIGS. 11 to 16 show schematic sectional representations of method steps for the production of exemplary embodiments of here-described optoelectronic semiconductor components,

FIG. 17 shows a schematic sectional representation of a housing for exemplary embodiments of here-described optoelectronic semiconductor components,

FIG. 18 shows a schematic plan view onto an exemplary embodiment of a here-described optoelectronic semiconductor component,

FIG. 19 shows a schematic sectional representation of a baseplate for exemplary embodiments of here-described optoelectronic semiconductor components,

FIG. 20 shows a schematic perspective representation of an exemplary embodiment of a here-described optoelectronic semiconductor component, from diagonally above,

FIG. 21 shows a schematic perspective sectional representation of the optoelectronic semiconductor component of FIG. 20,

FIG. 22 shows a schematic perspective representation of the optoelectronic semiconductor component of FIG. 20 from diagonally above,

FIGS. 23 to 25 show schematic sectional representation of housings for exemplary embodiments of here-described optoelectronic semiconductor components,

FIGS. 26 to 30 show schematic sectional representations of steps of a production method for exemplary embodiments of here-described optoelectronic semiconductor components, and

FIGS. 31 and 32 show schematic sectional representations of gas exchange channels for exemplary embodiments of here-described optoelectronic semiconductor components.

### DETAILED DESCRIPTION

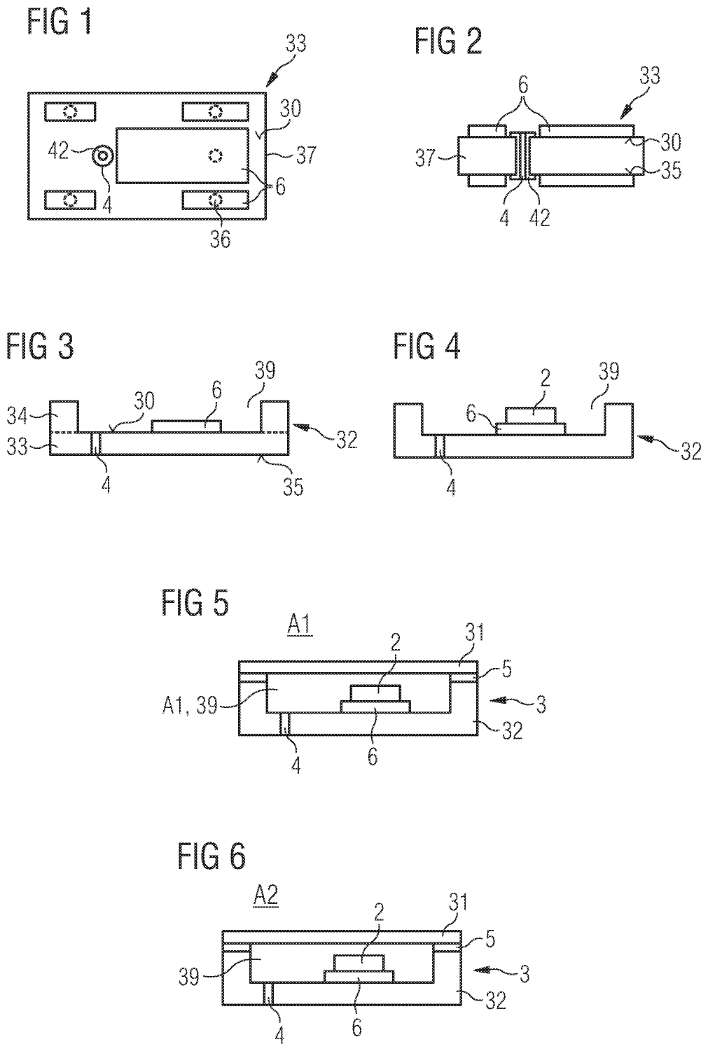

FIGS. 1 and 2 show an exemplary embodiment of a baseplate 33 for optoelectronic semiconductor components 1. The baseplate 33 preferably comprises a ceramic body 37 as carrying component. Furthermore, the preferably planar baseplate 33 comprises multiple metallic electrical connection regions 6, applied on the ceramic body 37. The thickness of the connection regions 6 is for example at least 30 μm and at most 0.3 mm, more particularly around 0.1 mm.

Corresponding connection regions 6 on a mounting side 30 and on an opposite bottom side 35 are connected to one another by electrical interlayer connections 36. The interlayer connections 36 are filled partially or completely in particular by a metal, and so the interlayer connections 36 are gastight.

The largest connection region 6 on the mounting side 30 is intended as a contact region for at least one optoelectronic semiconductor chip (not shown in the drawing), more particularly a laser diode.

The base plate 33, moreover, comprises a gas exchange channel 4, which passes completely through the baseplate 33 and hence through the ceramic body 37. The gas exchange channel 4 therefore represents a continuous opening through the baseplate 33. The gas exchange channel 4 preferably comprises a metallization 42, composed of or comprising nickel, for example. The metallization 42 is markedly thinner than the connection regions 6; for example, the thickness of the metallization 42 is almost 10% or at most 20% or at most 60% of the thickness of the connection region 6 on the corresponding side of the baseplate 33. This is preferably the case for all other exemplary embodiments as well.

The width of the metallization 42 around the gas exchange channel 4, seen in plan view onto the bottom side 35 or onto the mounting side 30, is for example at least once or at least twice or at most ten times or at most five times an internal diameter of the gas exchange channel 4 on the bottom side 35 or on the mounting side 30. Seen in plan view, the metallization 42 is, for example, round, more particularly circular, or polygonal in design. This is preferably the case for all other exemplary embodiments as well.

The metallization 42 may also be located on the mounting side 30 and on the bottom side 35 and may completely cover side walls of the gas exchange channel 4. The metallization 42 is preferably separate electrically from the connection regions 6.

Illustrated in FIGS. 3 to 7 is an exemplary embodiment of a production method for optoelectronic semiconductor components 1. According to FIG. 3, a main housing body 32 is provided. The main housing body 32 may have a one-piece design. Alternatively the main housing body 32 is composed of the baseplate 32 and a carrier ring 34, symbolized in FIG. 3 by a dashed line. In that case the baseplate 32 may have a construction as represented in FIGS. 1 and 2. The main housing body 32 therefore has a cavity 39.

According to FIG. 4, an optoelectronic semiconductor chip 2 is applied, by means of soldering, for example, in the cavity 39 on the connection region 6. To simplify the representation, only one connection region 6 and only one semiconductor chip 2 are drawn in FIGS. 3 to 7, there being preferably multiple semiconductor chips 2 and multiple connection regions 6 present.

In the step of FIG. 5, a housing cover 31 is installed on the main housing body 32, to form a housing 3. In this case a connection is made between the housing cover 31 and the main housing body 32 by the processing of a connecting means 5, which is for example a soft solder, more particularly AuSn.

In order to ensure high quality of the connection between the housing cover 31 and the main housing body 32, there is a first atmosphere A1 present. The first atmosphere A1 is preferably a forming gas or an inert gas. A particular effect of the first atmosphere A1 is to prevent the formation of an oxide layer on the connecting means 5.

The housing cover 31 therefore seals the cavity 39 in a direction away from the main housing body 32. Consequently there is likewise the first atmosphere A1 located in the cavity 39.

In the step of FIG. 6, the first atmosphere A1 is replaced with a second atmosphere A2. This is accomplished more particularly by evacuating the environment of the housing 3, meaning that the first atmosphere A1 is removed. Thereafter the second atmosphere A2 is applied.

Through the gas exchange channel 4, accordingly, the first atmosphere A1 is drawn off and the second atmosphere A2 is brought into the cavity 39. The second atmosphere A2 is, for example, dried air having an oxygen fraction of around 21%. As a result of the high oxygen fraction in the second atmosphere A2, any organic components deposited on a laser facet of the semiconductor chip 2 can be oxidized, and hence it is possible to extend the lifetime of the semiconductor component 1.

The first and/or second atmospheres A1, A2 are preferably at approximately standard pressure. This means that at room temperature, i.e., 294 K, the pressure of the first and/or second atmospheres A1, A2 is preferably between 0.8 bar and 1.2 bar inclusive.

According to FIG. 7, lastly, the gas exchange channel 4 is sealed thermally and durably with a seal 7, and so the housing 3 becomes hermetically impervious. It is possible here, as in all other exemplary embodiments, for the seal 7 to be installed only externally on the gas exchange channel 4, and so the gas exchange channel 4 itself remains free of the seal 7.

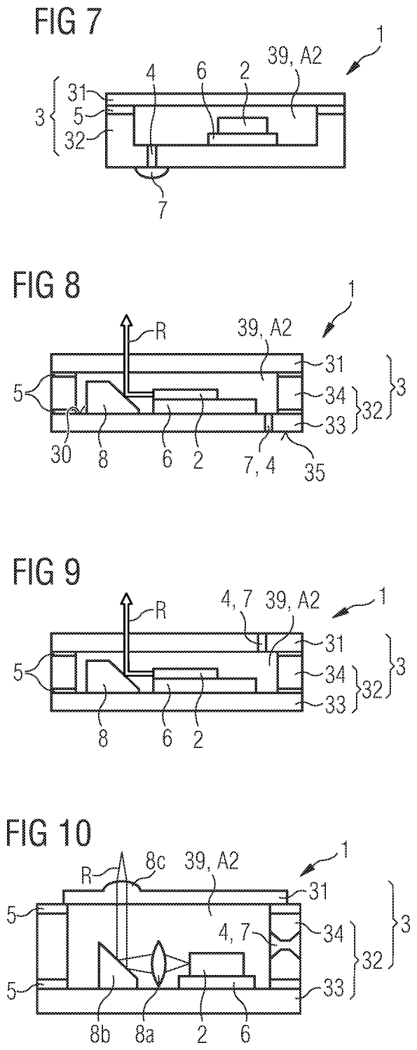

FIG. 8 represents a further exemplary embodiment of the optoelectronic semiconductor component 1. Additionally installed in the cavity 39 is an optical unit 8, as for example a deflecting prism. By means of the optical unit 8, the radiation R generated in operation, which is preferably visible laser light, is guided in a direction toward the housing cover 31 and through the housing cover 31. For this purpose the housing cover 31 preferably has on each of its two sides an optically active coating (which is not shown in the drawing), more particularly an antireflection coating.

The housing 3 in FIG. 8, furthermore, is composed of the housing cover 31, the carrier ring 34, and the baseplate 33, these components being connected to one another by the connecting means 5. In the baseplate 33, the gas exchange channel 4 is located adjacent to the semiconductor chip 2 and also adjacent to the electrical connection region 6. Again, for simplification of the representation, only one connection region 6 is drawn in, there being preferably multiple connection regions 6 present, including, in particular, on the bottom side 35 of the housing.

The gas exchange channel 4 may be filled completely with the seal 7. The cavity 39 is filled with the second atmosphere A2.

The statements made in relation to FIGS. 1 to 7 are equally valid, moreover, for FIG. 8.

The exemplary embodiment of FIG. 9 includes an illustration that the gas exchange channel 4 is located in the housing cover 31, specifically in a region which is properly not accessed by the radiation generated in operation. The housing cover 31 is composed, for example, of glass. The statements made in relation to FIGS. 1 to 8 are equally valid, moreover, for FIG. 9.

In the exemplary embodiment of FIG. 10 it is shown that the gas exchange channel 4 is located in the carrier ring 34—a ceramic carrier ring for example—and therefore runs preferably parallel to the mounting side 30. The gas exchange channel 4 is shaped optionally as a double cone, in which case there may be a cylindrical middle portion. Instead of the cylindrical shape of the gas exchange channel 4 in FIGS. 1 to 9, it is also possible in each case to use a double-conical gas exchange channel 4 of this kind.

As in all the other exemplary embodiments, it is possible for the housing cover 31 to be shaped as an optical unit 8c in a radiation transient region. Additionally the deflecting optical unit 8b may be present, and as a further option, there is a focusing optical unit 8a on the at least one semiconductor chip 2.

Just as in all the other exemplary embodiments, furthermore, it is not necessary for the housing cover 31 to have to finish flush with the main housing body 32. As in all of the other exemplary embodiments, electrical connecting means for the at least one semiconductor chip 2, such as bond wires, are not drawn in, in order to simplify the representation.

The statements made in relation to FIGS. 1 to 9 are equally valid, moreover, for FIG. 10.

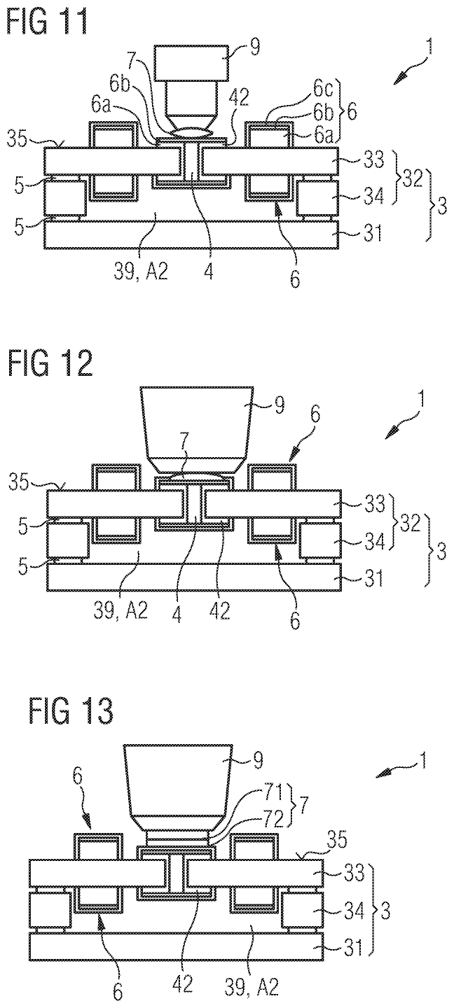

Shown in FIGS. 11 to 16 are various methods by which the seal 7 can be installed on the gas exchange channel 4. The methods, which therefore correspond to the step of FIG. 7, are each illustrated only for one particular type of the gas exchange channel 4, but may also be employed analogously for other types of gas exchange channels 4, not explicitly drawn in. Where they are drawn in, the connection regions 6 are in each case thicker than the metallization 42 present preferably on the gas exchange channel 4, and other configurations are also possible. The method steps, not drawn in on FIGS. 11 to 16, each preferably take place in the same way as described in connection with FIGS. 3 to 6.

According to FIG. 11, the seal 7 is formed by a low-melting glass, which is applied and/or pressed onto the metallization 42 and the gas exchange channel 4 by a sealing tool 9, which is, for example, a heating die and/or an applicator nozzle. Because the low-melting glass joins with the metallization 42, the sealing of the gas exchange channel 4 is hermetically impervious. The connection regions 6 protrude beyond the completed seal 7 in a direction away from the baseplate 33.

Seen in cross section, the metallization 42 is preferably H-shaped in design, and so the metallization 42 covers the side walls of the gas exchange channel 4 completely and all around. Furthermore, the metallization 42 runs on the main sides of the component through which the gas exchange channel 4 runs, all around the actual channel. This means that in FIG. 11, the metallization 42 extends with a relatively low thickness onto the mounting side 30 and onto the bottom side 35 of the baseplate 33.

The connection regions 6 here are formed preferably by three metallic layers 6a, 6b, 6c. The relatively thick layer 6a closest to the baseplate 33 is composed, for example, of gold or copper. The middle layer 6b is composed more particularly of nickel, and the third layer 6c, which may envelop the other layers 6a, 6b, is composed for example of gold, palladium and/or platinum. In that case, on the bottom side 35, the metallization 42 is formed, for example, by removal of the layer 6c, by laser ablation, for example, with the middle layer 6b being consequently exposed. On the mounting side 30 the metallization 42 of the gas exchange channel 4 may comprise all three layers 6a, 6b, 6c. The innermost layer 6a in this case of the metallization 42 is preferably markedly thinner than in the case of the connection regions 6, by a factor, for example, of at least 4 and/or by a factor of at most 20.

It is possible accordingly for a sealing spot to be recessed relative to the component surface. This means that the sealing spot, more particularly the point of installation of the seal 7 on the gas exchange channel 4, can be situated at a different height from outer sides of the connection regions 6, in order specifically to be able to ensure an even bottom side 35 of the housing. In an alternative to the situation shown, there may for this purpose be a recess present for the seal 7 on the bottom side 35 of the housing, as is also possible in all the other exemplary embodiments.

In FIG. 12, conversely, it is shown that the seal 7 is formed by a metal ball or stud bump, preferably composed of gold, which is installed on the metallization 42 by means of frictional welding. This means that sealing tool 9 may be a bond wire tool and/or a soldering apparatus.

According to FIG. 13, the seal 7 is formed by a carrier plate 71, on which there is a sealing layer 72. In this case the sealing tool 9 may be a bonding tool. The carrier plate 71 is composed, for example, of a semiconductor material such as silicon or else of a metal. The sealing layer 72 is more particularly a gold layer. Where the metallization 42 is composed of gold, for instance, the seal 7 may be realized by a gold-gold connection, in particular by frictional welding.

Instead of the carrier plate 71 with the sealing layer 72 it is also possible to employ a relatively thick, one-piece metal platelet, specifically of gold, for the seal 7.

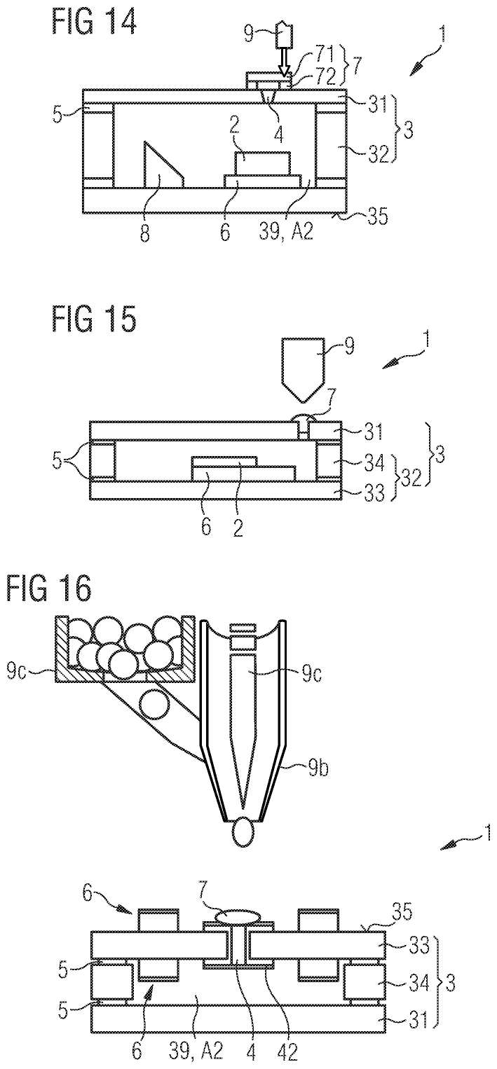

In FIG. 14, the seal 7 is generated from a glass plate for the carrier plate 71 and from a glass solder as sealing layer 72. In a deviation from the representation in FIG. 14, the sealing layer 72 may also be installed over the whole area of the carrier plate 71. In that case, for example, the seal 7 is generated by the use, as sealing tool 9, of a laser, which melts the sealing layer 72 and connects it to the housing cover 31. Alternatively the sealing tool 9 is a heating head. The gas exchange channel 4 may therefore be free from a metallization.

Also illustrated in FIG. 14 is that the gas exchange channel 4 optionally has the shape of a conical frustum. The same is possible in all of the other exemplary embodiments.

In the case of the exemplary embodiment of FIG. 15, the seal 7 is implemented by application of a glass drop. The glass drop is applied by means of a hot dispensing process directly onto the housing cover 31, which is preferably a glass plate. The sealing tool 9 used is, in particular, a glass dispensing head. The low-melting solder glass for the seal flows into the gas exchange channel 4, which it hermetically seals. As a result of glass solders of this kind, preferably having very low melting points, there is no thermal damage to the semiconductor components 1. This operation therefore generates a glass-glass assembly in the housing cover 31.

The illustration in FIG. 15 also includes the connecting means 5 finishing flush with the housing cover 31, the optional carrier ring 34, and the base plate 33, in contrast, for example, to FIG. 13, whereby the connecting means 5 has a set-back arrangement relative to the housing cover 31, the optional carrier ring 34, and the baseplate 33. Both configurations are in each case possible in all exemplary embodiments.

In order to obtain an even outer side of the housing cover 31, the housing cover 31 may, in the region of the gas exchange channel 4, be provided with a recess (not shown in the drawing), so that the seal 7 can be countersunk in the housing cover 31 and in that case does not protrude beyond the housing cover 31, in a direction away from the mounting side 30. This may be true in all of the other exemplary embodiments, including in relation to the baseplate 33, according to FIG. 7, for instance, and in relation to the carrier ring 34, according to FIG. 10, for instance.

According to FIG. 16, the sealing tool 9 comprises a solder ball reservoir 9a, a nozzle 9b, and a laser 9c. As a result, heated solder balls, composed in particular of AuSn, can be shot onto the gas exchange channel 4, and connected to the metallization 42. Since this operation can take place very quickly, it is almost possible to prevent oxidation of the hot solder balls in the oxygen-containing second atmosphere A2.

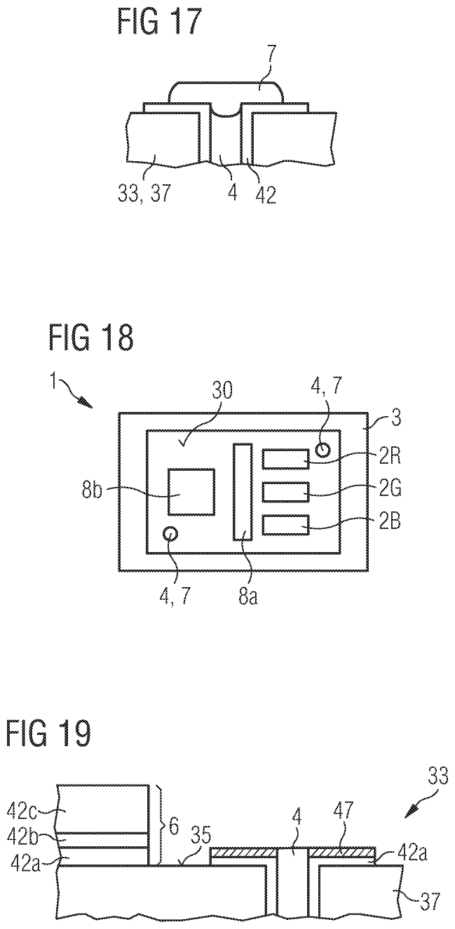

In FIGS. 11 to 16, in a simplified representation, the seal 7 is located in each case only on the gas exchange channel 4, and not in the gas exchange channel 4. In deviation from this, the seal 7 may also slightly fill the gas exchange channel 4 in each case—see FIG. 17.

The statements made in relation to FIGS. 1 to 10 are equally valid, moreover, for FIGS. 11 to 17.

FIG. 18 shows that the optoelectronic semiconductor component 1 comprises a laser diode 2R for red light, a laser diode 2G for green light, and a laser diode 2B for blue light. This means that the semiconductor component 1 is an RGB laser module. This is preferably also the case for all other exemplary embodiments.

Shown as an option in FIG. 18, furthermore, is the possible presence of more than one gas exchange channel 4, as also possible in all other exemplary embodiments. However, the version with only exactly one gas exchange channel 4 is preferred.

The statements made in relation to FIGS. 1 to 17 are equally valid, moreover, for FIG. 18.

Illustrated in FIG. 19, lastly, is the possibility of the metallization 42 of the gas exchange channel 4 being composed of only one of the layers 42a, 42b, 42c of the connection regions 6, more particularly of the bottommost layer 42a. The same applies to all other exemplary embodiments.

On a top side of the metallization 42, in other words, more particularly, on a top side of the layer 42a, a thin oxide layer may be formed, as indicated by hatching in FIG. 19. Where the layer 42a is of nickel, for example, the oxide layer is composed of NiO. This is advantageous especially for a hermetic sealing by means of a low-melting glass as the seal 7—compare, in particular, FIG. 11.

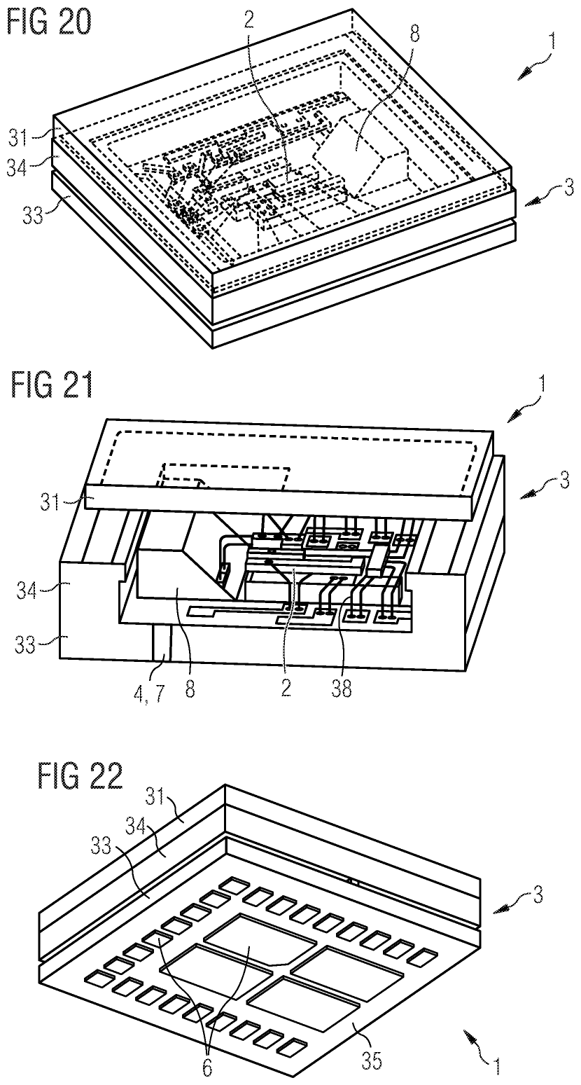

FIGS. 20 to 22 show a further exemplary embodiment of the optoelectronic semiconductor component 1. In this case the at least one optoelectronic semiconductor chip 2 is located optionally on an intermediate carrier 38, also referred to as a submount. The at least one gas exchange channel 4 is located for example in the baseplate 33. On the bottom side 35 of the housing there may be two or more of the metallic electrical connection regions 6 installed. For example, four larger connection regions 6 are located in a central region of the bottom side 35 of the housing. The larger connection regions 6 are optionally surrounded all round by multiple smaller connection regions 6.

The statements made in relation to FIGS. 1 to 19 are equally valid, moreover, for FIGS. 20 to 22.

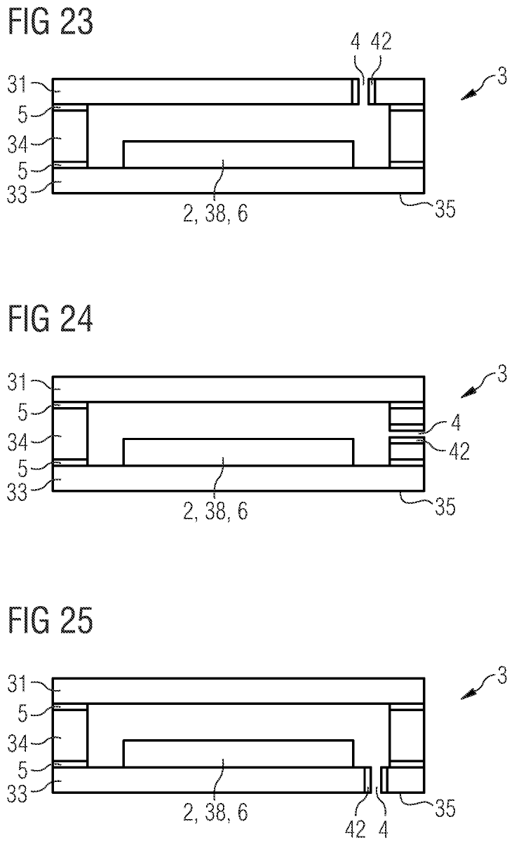

Illustrated in FIGS. 23 to 25 is the possibility of the gas exchange channel 4 in the housing 3 being located either in the housing cover 31—see FIG. 23; in the carrier ring 34—see FIG. 24; or in the baseplate 33—see FIG. 25. Combinations of the configurations of FIGS. 23 to 25 are also possible. Furthermore, FIGS. 23 to 25 show that optionally there may in each case be the intermediate carrier 38 present.

The gas exchange channels 4 according to FIGS. 23 to 25 are preferably each provided with the metallization 42 before the installation of the intermediate carrier 38 and of the semiconductor chip 2.

The statements made in relation to FIGS. 1 to 22 are equally valid, moreover, for FIGS. 23 to 25, and vice versa.

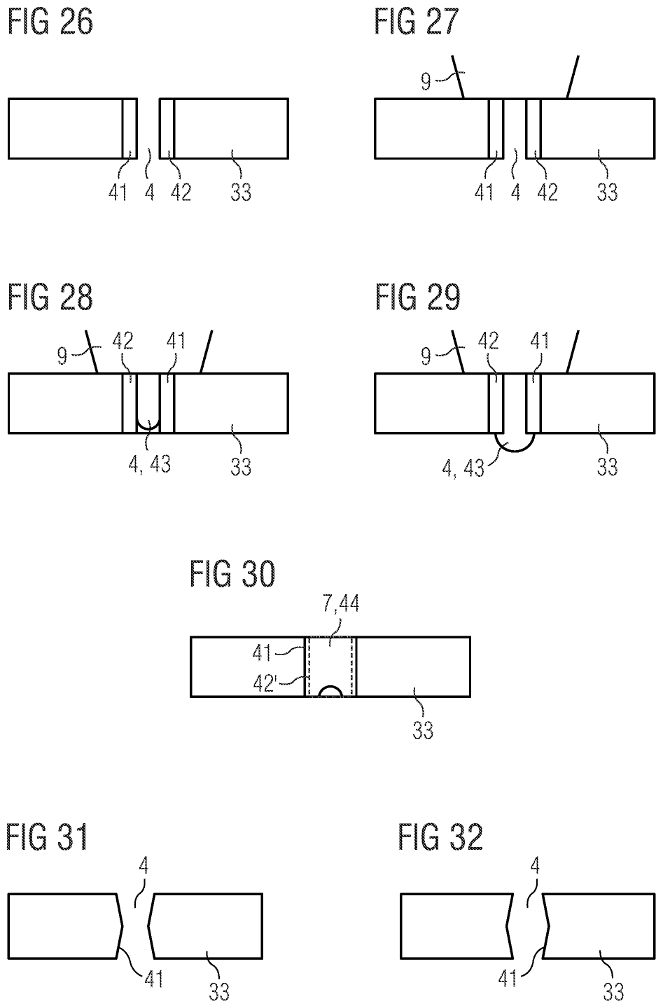

FIGS. 26 to 30 represent a number of steps in a possible production method, relating to the sealing of the at least one gas exchange channel 4. The other method steps, independently of the sealing of the at least one gas exchange channel 4, are not illustrated in FIGS. 26 to 30, for the sake of simplicity. Illustratively, the at least one gas exchange channel 4 is located in the baseplate 33, in analogy to FIG. 25. In deviation from this, with the production method described, the at least one gas exchange channel 4 may alternatively be located—just as in accordance for instance with FIG. 23 or 24—in the carrier ring 34 and/or in the housing cover 31.

According to FIG. 26, for example, the baseplate 33 is provided, and comprises the gas exchange channel 4. The gas exchange channel 4 has a cylindrical shape, for example. In particular before the installation of the optional intermediate carrier 38 and also of the semiconductor chip 2, the metallization 42 is already generated on inner sides 41 of the gas exchange channel 4, by means of sputtering, vapor deposition and/or electroplating, for example.

The thickness of the metallization 42 is for example at least 10% and/or at most 25% of the mean diameter of the gas exchange channel 4. The mean diameter of the gas exchange channel 4 is for example at least 10 μm and/or at most 0.1 mm. The metallization 42 is composed for example of gold or of copper, nickel, zinc and/or tin.

FIG. 27 shows the application of the sealing tool 9, which for example is a dispensing head, to the gas exchange channel 4. The sealing tool 9 is preferably pressed firmly onto the region around the gas exchange channel 4, so that the sealing tool 9 seals around the gas exchange channel 4.

In the step of FIG. 28, the sealing tool 9 is used to bring—for example, to press—a liquid alloy metal 43 into the gas exchange channel 4. The alloy metal 43, which in particular is applied at approximately room temperature or at a temperature slightly above room temperature, comprises, for example, gallium, a mixture of gallium and indium or mercury.

30 It is possible—see FIG. 28—for the alloy metal 43 only to fill the gas exchange channel 4 incompletely. Alternatively the alloy metal 43 may fill the gas exchange channel 4 completely and may reach to an outer side of the gas exchange channel 4 that is opposite the sealing tool 9—see FIG. 29. In respect of the metallization 42, the alloy metal 43 is preferably wetting and is optionally not wetting in respect of the material of the housing 3 around the gas exchange channel 4.

FIG. 30 illustrates the reaction of the alloy metal 43 with the metallization 42, to form a sealing alloy 44 which hermetically seals off the gas exchange channel 4. This reaction is more particularly an amalgamation. This reaction may take place, for example, at room temperature or at temperatures slightly above room temperature. It is possible for the sealing tool 9 to be still present at least some of the time during this reaction, in order, for example, to carry out heating or to exert a pressure, or for the sealing tool 9 to have already been removed, as illustrated in FIG. 30.

It is not necessary for the alloy metal 43 and/or the metallization 42 to be used up completely in forming the sealing alloy 44. Hence optionally there may still be a metallization residue 42′ remaining on the inner wall 41. Excess alloy metal 43 may where necessary be removed after the sealing of the gas exchange channel 4, using, for example, a jet of warm water, a dilute acid, such as low-percentage-concentration KOH or HCl, or using buffered hydrofluoric acid. The material of the housing 3 around the gas exchange channel 4 is, for example, silicon nitride, glass and/or silicon.

FIGS. 31 and 32 further illustrate how the gas exchange channel 4 may have not only a cylindrical shape, but may instead, seen in cross section, also be, for example, biconcave—see FIG. 31—or biconvex—see FIG. 32.

The statements made in relation to FIGS. 1 to 25 are equally valid, moreover, for FIGS. 26 to 32, and vice versa.

With the method of FIGS. 26 to 32 in particular, therefore, it is possible to achieve a hermetic sealing of holes 4 by means of amalgam reaction with gallium alloys or with mercury alloys. As a result of the hermetic sealing, particularly in a late fabrication step, targeted product properties can be realized under readily controllable ambient conditions, as under protective gas, for example. This applies specifically, though not only, to the fabrication of laser modules or LED modules, in order to protect them from moisture, for instance.

A hermetic sealing of a hole 4 is therefore achieved, in order for example to produce a desired gas atmosphere in a hollow-space component through a small hole 4 and to seal the hole 4 under this atmosphere and without great temperature loading. The sealing is to be sufficiently gastight and to be resistant mechanically and with respect to higher temperatures.

With the method described here it is possible to seal an internally metallized small hole 4, also referred to as a via, and hence a hollow space enclosed by the housing 3, in a durable and gastight manner by simple dispensing of a low-melting alloy metal 43, such as gallium at above 30° C., gallium-indium at room temperature, or mercury, likewise at room temperature. Given appropriate choice of the metal fractions in the inner wall 41 of the hole, i.e. the metallization 42, and in the liquid alloy metal 43 dispensed, the stable, relatively high-melting sealing alloy 44 is formed.

After a temperature-dependent hardening time, the sealing alloy 44 has a markedly higher melting point than the dispensed liquid metal 43. Through a combination of a suitable shape for the hole 4 and the expansion inherent in formation of the alloy, the resulting system is a mechanically imperviously closed-off system.

Illustrative combinations of materials are as follows:
metallization 42 on the inner hole wall 41, approximately 60% of the sealing alloy 44: gold; as a result of this there is no oxidation of the metallization 42, and so the reaction with the alloy metal 43 is not hindered by an oxide layer;
dispensed alloy metal 43, 40% of the sealing alloy 44: 100% gallium or a mixture of 70% gallium and 30% indium; the stated percentages are valid in particular with a tolerance of at most 15 percentage points or at most five percentage points.
Alternatively: metallization 42 on the inner hole wall 41 of copper or of nickel, zinc, tin, and dispensed alloy metal 43: mercury.

Gallium wets a host of materials very well by itself. Where the contact is forced by injection into the hole 4 and the formation of alloy has started, the components Ga and metal of the metallization 42 remain joined until through-hardening. In the case of difficulties in getting the Ga durably into the hole 4 owing to pressure conditions, external pressure control may possibly be needed. The hardening or through-reaction may take some time and proceeds more quickly at elevated temperature. In the case of too high a temperature, however, the reaction of Au with Ga may proceed exothermically and so the temperatures employed ought not to be too high.

The method described can be carried out simply in process engineering terms at approximately room temperature and the handling of the materials involved is uncomplicated. The method is compatible with numerous ambient atmospheres and gases and can also be carried out even in a vacuum or at reduced pressure. As a result of the very low vapor pressure of liquid gallium or of liquid mercury, there is no undesirable Ga or Hg contamination within the housing 3 prior to the hardening.

The components shown in the figures preferably follow one another, and more particularly follow one another directly, in the order specified, unless otherwise described. Components which do not make contact with one another in the figures preferably have a distance from one another. If lines are drawn as parallel to one another, the assigned faces are preferably likewise aligned parallel to one another. Furthermore, the relative positions of the components drawn with respect to one another are reproduced correctly in the figures, unless otherwise specified.

The invention described here is not restricted by the description with reference to the exemplary embodiments. The invention instead embraces any new feature and also any combination of features, this involving more particularly any combination of features in the claims, even if that feature or that combination is not itself explicitly specified in the claims or exemplary embodiments.

1. An optoelectronic semiconductor component comprising:
at least one optoelectronic semiconductor chip for generating a radiation, and
a housing in which the at least one optoelectronic semiconductor chip is hermetically encapsulated, wherein
the housing comprises a housing cover which is secured on a main housing body using a connecting means,
the housing comprises a gas exchange channel,
the gas exchange channel is hermetically sealed with a seal,
the main housing body comprises a baseplate which is opaque for the radiation, as a carrier for the at least one optoelectronic semiconductor chip, and the baseplate bears metallic electrical connection regions on both sides, and the housing cover is configured as a radiation exit window for the radiation,
the gas exchange channel is electrically and optically function-free, and
the gas exchange channel is located in the baseplate and comprises a metallization which extends onto a bottom housing side of the baseplate and at least on the bottom housing side is thinner than the electrical connection regions, so that the electrical connection regions on the bottom housing side protrude beyond the gas exchange channel and the seal in a direction away from the main housing body.

2. The optoelectronic semiconductor component of claim 1,
wherein the housing comprises exactly one gas exchange channel.

3. The optoelectronic semiconductor component of claim 1,
wherein the gas exchange channel, viewed in plan view onto a mounting side of the main housing body, is located adjacent to the at least one optoelectronic semiconductor chip.

4. The optoelectronic semiconductor component of claim 1,
wherein the main housing body comprises a carrier ring on a side facing the housing cover.

5. The optoelectronic semiconductor component of claim 1,
wherein the seal comprises or is a low-melting glass and the low-melting glass has a melting point of at most 500° C.

6. The optoelectronic semiconductor component of claim 1,
wherein the seal comprises gold, gallium and/or indium or is composed of gold, gallium and/or indium.

7. The optoelectronic semiconductor component of claim 1,
wherein the seal comprises or consists of a metallic solder.

8. The optoelectronic semiconductor component of claim 1,
wherein the seal comprises a carrier plate and a sealing layer, with the sealing layer being located between the carrier plate and the metallization.

9. The optoelectronic semiconductor component of claim 1,
wherein a mean diameter of the gas exchange channel is at least 10 μm and at most 0.2 mm,
wherein a thickness of the housing directly at the gas exchange channel exceeds the mean diameter of the gas exchange channel by a factor of at least two, and
wherein the gas exchange channel is filled only partially or completely with the seal.

10. The optoelectronic semiconductor component of claim 1,
which is a laser module for generating red, green, and blue, and
which is surface-mountable.

11. The optoelectronic semiconductor component of claim 1,
wherein the gas exchange channel has the shape of a cylinder, a conical frustum or a double cone.

12. The optoelectronic semiconductor component of claim 1,
wherein the housing cover is composed of a glass and the main housing body is based on at least one ceramic, and
wherein at least one optical unit for the radiation is located in the housing.

13. A method for producing an optoelectronic semiconductor component having a housing comprising:
A) equipping a main housing body with at least one optoelectronic semiconductor chip, the main housing body having at least one gas exchange channel,
B) installing a housing cover on the main housing body, and
D) sealing the gas exchange channel with a seal, so that the housing is hermetically sealed.

14. The method of claim 13,
wherein step D) comprises:
D1) coating an inner side of the gas exchange channel with a metallization,
D2) introducing at least one liquid alloy metal into the gas exchange channel onto the metallization, and
D3) hardening to form the seal, the at least one alloy metal reacting with the metallization to form a sealing alloy which has a higher melting point than the at least one alloy metal.

15. The method of claim 14,
wherein
the metallization comprises or consists of gold and/or copper,
the alloy metal comprises or consists of mercury and/or gallium and
the hardening is carried out at a temperature between 15° C. and 150° C. inclusive and lasts at least 2 h.

16. The method of claim 13, with which an optoelectronic semiconductor component is produced, comprising the following method steps carried out in the order specified:
A) equipping the main housing body with the at least one optoelectronic semiconductor chip,
B) installing the housing cover on the main housing body, there being a first atmosphere (A1) present in the housing for the working of the connecting means,
C) replacing the first atmosphere in the housing with a second atmosphere through the open gas exchange channel, and
D) sealing the gas exchange channel with the seal, so that the housing is hermetically sealed.

17. The method of claim 16,
wherein the first atmosphere is a protective gas atmosphere and the second atmosphere is oxygen-containing.

18. A baseplate for an optoelectronic semiconductor component according to claim 1, wherein
the baseplate is configured as a carrier for at least one optoelectronic semiconductor chip,
the baseplate bears metallic electrical connection regions on both sides, for the electrical interconnection of the at least one optoelectronic semiconductor chip,
a gas exchange channel is located in the baseplate and comprises a metallization,
the metallization at least on a bottom side of the baseplate, which lies opposite a mounting side for the at least one optoelectronic semiconductor chip, is thinner than the electrical connection regions,
the electrical connection regions on the bottom side protrude beyond the gas exchange channel in a direction away from the baseplate,
the gas exchange channel, seen in plan view onto the mounting side, is located adjacent to a region intended for the at least one optoelectronic semiconductor chip and is electrically insulated from the electrical connection regions,
the gas exchange channel on the bottom side has a fraction of at most 1%,
the baseplate is opaque for visible light, and
the gas exchange channel is electrically and optically function-free.
